(19) United States
(12) Patent Application Publication
(10) Pub. No.: US 2026/0072064 A1
(43) Pub. Date: Mar. 12, 2026

(54) DEVICE FOR MEASURING THE ELECTROMAGNETIC RADIATION OF A RADIATING OBJECT

(71) Applicant: ANYFIELDS, Toulouse (FR)

(72) Inventors: Nicolas CAPET, Toulouse (FR); Daniel PROST, Toulouse (FR)

(73) Assignee: ANYFIELDS, Toulouse (FR)

(21) Appl. No.: 18/856,594

(22) PCT Filed: Apr. 7, 2023
(86) PCT No.: PCT/EP2023/059320

§ 371 Date: Jul. 27, 2025

(30) Foreign Application Priority Data
Apr. 11, 2022 (FR) FR2203286

(51) Int. Cl. G01R 29/08; H04N 23/20; H04N 23/56

(52) U.S. Cl. CPC G01R 29/0878; H04N 23/20; H04N 23/56

(57) ABSTRACT

The invention relates to a device for measuring the electromagnetic radiation of a radiating object (10), comprising: a sealed box (20) housing said radiating object (10); means (12) for moving said radiating object (10) in a longitudinal direction (L); a heat-sensitive film (14) housed in said box (20); a camera (16) housed at a longitudinal end of said sealed box (20), opposite said radiating object (10) to be measured relative to the heat-sensitive film (14), and configured to acquire images of said heat-sensitive film; means (18) for processing said images configured to provide a map of the electromagnetic field of said radiating object (10) picked up by said heat-sensitive film (4).

### TECHNICAL FIELD OF THE INVENTION

The invention relates to a device for measuring the electromagnetic radiation of a radiating object, such as an antenna, in particular at radio or microwave frequencies.

### TECHNOLOGICAL BACKGROUND

The electromagnetic radiation of a radiating object, such as an antenna, a radiotelephone, a microwave transceiver, a microwave device, an induction device, etc., often needs to be known.

To this end, document WO 2020/0351193 proposes a device for measuring the performance capabilities of a radiating object in at least two different frequency bands. This device comprises an external housing forming an external chamber provided with radiofrequency reflecting walls, an internal chamber provided with radiofrequency absorbing walls in which the tested radiating object is housed, a first arrangement of test antennas housed in the external chamber for measuring in a first frequency band and a second arrangement of test antennas arranged inside the internal chamber for measuring in the second frequency band.

This device therefore allows the performance capabilities of the radiating object to be measured in a reflecting radiofrequency environment by the first arrangement of test antennas and the performance capabilities to be measured in a basically anechoic radiofrequency environment by the second arrangement of test antennas.

This solution does not allow the electromagnetic radiation of an antenna radiating object to be characterized, it only allows the performance capabilities of the radiating object to be measured in predetermined frequency bands. Furthermore, this solution is complex to implement and requires the use of two sets of test antennas.

Therefore, the inventors have attempted to develop a simpler integrated device that allows a radiating object to be characterized and the radiation pattern to be reconstructed.

### AIMS OF THE INVENTION

The invention aims to provide a device for measuring, characterizing and visualizing the electromagnetic radiation of a radiating object.

The invention particularly aims to provide such a measuring device that allows measurement, characterization and visualization of the radiation of the object for various frequencies.

The invention particularly aims to provide such a measuring device that does not require the use of complex components and that has a limited number of components.

The invention particularly aims to provide such a measuring device that can be used by anyone without significant problems, without any particular technical knowledge of the operation of the antennas.

The invention also aims to provide, in at least one embodiment, a handheld device for measuring and characterizing the electromagnetic radiation of a radiating object.

### DISCLOSURE OF THE INVENTION

To this end, the invention relates to a device for measuring the electromagnetic radiation of a radiating object, comprising:
a sealed box, impervious to electromagnetic radiation, extending in a longitudinal direction and equipped with an opening adapted to allow said radiating object to be measured to be housed in said box;
means for modulating the radiation of said radiating object.

The device according to the invention is characterized in that it further comprises:
means for moving said radiating object inside the sealed box in the longitudinal direction between a position, called proximal position, and a position, called distal position;
a heat-sensitive film, heat-sensitive to the electromagnetic field, housed in said sealed box and extending in a plane perpendicular to said longitudinal direction in the vicinity of said proximal position;
a camera housed at a longitudinal end of said sealed box, opposite said radiating object to be measured relative to the heat-sensitive film, and configured to acquire images of said heat-sensitive film, with said heat-sensitive film being arranged at the focal distance from said camera;
means for processing said images acquired by said camera configured to provide a map of the electromagnetic field picked up by said heat-sensitive film.

The device according to the invention thus allows the electromagnetic field of a radiating object to be measured and a map to be provided. In particular, and according to the invention, the heat-sensitive film heats in contact with the electromagnetic radiation of the radiating object. This heating is imaged by the camera, then detected and characterized by the image processing means. The heat-sensitive film can be sensitive either to the magnetic field or to the electric field. The heat-sensitive film is arranged at the focal distance from the camera.

The device according to the invention allows any type of radiating object that can be housed in the sealed box to be tested, thus eliminating the need to use an anechoic chamber or reverberation chamber of the solutions of the prior art. In particular, the device according to the invention allows images to be obtained of the field radiated by a radiofrequency and/or microwave source without any special precautions. Such a device therefore can be used in a classroom, a design office and generally in any room not specifically designed for electromagnetic radiation.

Throughout the text, and in accordance with the uses, the radio waves (or Hertzian waves) are considered to refer to the electromagnetic waves with frequencies ranging between 3 Hz and 300 MHz and the microwaves are considered to refer to the electromagnetic waves with frequencies ranging between 300 MHz and 300 GHz.

The device according to the invention is an integrated device that does not require any external equipment other than an energy source for electrically powering the radiating source, the camera, the image processing means and the means for longitudinally moving the radiating object. According to an advantageous variant, this source of electrical energy is formed by a rechargeable battery housed in a compartment adjacent to the sealed housing.

Furthermore, the device according to the invention has the specific feature of allowing longitudinal movement of the radiating object relative to the heat-sensitive film (for example, using motorized means) between a distal position remote from the heat-sensitive film and a proximal position close to the heat-sensitive film, which allows the electromagnetic radiation of the radiating object to be measured in different planes located at different distances from the heat-sensitive film. The device according to the invention thus allows a 3D reconstruction of the near-field amplitude to be produced by the image processing means.

Furthermore, and in the case of an antenna, amplitude measurements in two distinct planes allow the phase of the field to be algorithmically reconstructed at any point of the aperture of the antenna, and thus allow the radiation pattern of this antenna to be reconstructed.

According to an advantageous embodiment, the camera is equipped with an image acquisition sensor in the visible domain and the device further comprises a monochromatic light source housed in said box and oriented toward the heat-sensitive film so as to illuminate it, with said film being coated with a layer of a fluorescent material.

According to this alternative embodiment, the device is equipped with a camera equipped with a CCD or CMOS sensor in the visible domain. This camera is provided with an optical filter adapted to the wavelength of the fluorescent light emitted by the heat-sensitive film covered with a fluorophore. Furthermore, a light source housed in the box illuminates the heat-sensitive film.

The fluorescent material must be a fluorophore that emits in the visible domain (approximately 400 nm to 800 nm) and with fluorescence intensity that depends on the temperature. According to one embodiment, the material that is used is Rhodamine B, the maximum fluorescence intensity of which is approximately 600 nm at ambient temperature when it is subjected to light with a wavelength of 470 nm and experiences a significant reduction in this intensity (approximately 2%/° C.) as its temperature rises. The difference between the wavelengths received by excitation and fluorescence facilitates measurement, because the filtering on the camera will allow the reflection of the emitted light on the film to be eliminated, without useful signal loss.

Of course, other materials that are both fluorescent and heat-sensitive can be used without casting doubt on the principle of this advantageous embodiment.

10 According to a second embodiment, the camera is a camera equipped with an infrared sensor.

In this case, the camera directly captures the heating of the heat-sensitive film.

Irrespective of the type of camera used (infrared or visible), the heat-sensitive film that is used is either weakly conductive (for the electric field measurement), or is insulating and has magnetic losses (for the magnetic field measurement). Thus, under the effect of the electromagnetic field of the radiating object, the film heats (typically within a range of 0.01 to 10° C.).

This heating is directly recorded by the infrared camera (for the infrared version), or is even responsible for a variation in the fluorescence intensity (for the fluorescence version) recorded by the camera in the visible domain.

Advantageously, the measuring device further comprises a filter arranged between the radiating object to be measured and the heat-sensitive film, with this filter being configured to filter a component of the electromagnetic field so as to allow measurement of the other components of the electromagnetic radiation of the radiating object to be measured.

Thus, and according to this advantageous variant, a filter is interposed between the radiating object and the heat-sensitive film. This filter assumes, for example, the form of a second thin film, of the conductive grid or absorbent grid type or of the type with particular patterns. This filter allows only the non-filtered components to pass over the heat-sensitive film. It is thus possible to carry out a cross-polarization measurement, for example. In the case of circular polarization, the right/left nature also can be obtained with a filter film using suitable patterns, in particular polarization-selective surfaces (known by the acronym PSS).

According to an advantageous variant of the invention, the heat-sensitive film is detachably mounted inside said sealed box.

This variant allows the type of film to be easily and quickly changed. In particular, and according to the invention, the type of heat-sensitive film that is used determines the type of field (electric or magnetic) that can be measured. For the electric field measurement, a weakly conductive film is used. For the magnetic field measurement, an insulating and magnetic losses film is used.

This detachable assembly can be of any type. It can be, for example, a frame upon which the film is placed, with this frame being housed in guide rails on the internal walls of the box facing one another.

According to a particular embodiment of the invention, the heat-sensitive film is an anisotropic film for determining the direction of the field and its spatial variation or its degree of ellipticity as a function of the polarization of the field radiated by said object to be measured.

According to this advantageous variant, the anisotropic film comprises an array of patterns for determining the spatial variation of the amplitude and of the direction of the field (for linear polarization), or even the spatial variation of the amplitude and the degree of ellipticity (for circular polarization) of the field radiated by said radiating object.

Such an anisotropic film is a film with particular patterns (parallel strips, stars with 3 or more branches) that allows, in addition to the amplitude, the polarization of the electric field to be determined, including the degree of ellipticity in the case of circular polarization. With such an array of patterns, it is also possible to determine the spatial distribution of these amplitudes and polarizations in the plane.

According to a variant of the invention, said means for modulating the radiation of said radiating object comprise a microcontroller, a synthesizer and a radiofrequency or microwave amplifier housed in a dedicated compartment.

This variant allows the radiating object to be powered and controlled.

According to another variant of the invention, said means for modulating the radiation of said radiating object comprise:
a shutter screen arranged between said radiating object and said heat-sensitive film, with said shutter screen being configured to be able to transition from a state, called transparent state, in which the radiation of said radiating object can reach said heat-sensitive film, to a state, called opaque state, in which said screen prevents said radiation from said radiating object from reaching said heat-sensitive film;
control electronics configured to control said shutter screen between the opaque state and the transparent state, and vice versa.

This variant allows the fields of the non-cooperative objects to be measured. The shutter screen placed in front of the heat-sensitive film ensures the low-frequency modulation of the object by opening and closing at the aforementioned frequency of a few tenths to a few Hz. The shuttering can be achieved by electrical or mechanical means. A mechanical shutter is, for example, made up of two parallel gates, each masking 50% of the heat-sensitive film, with one laterally oscillating over a distance equal to the step of the gate, allowing 50% opening (superimposed gates) or closing (gates offset by one step). The electric shutter can be a liquid crystal or plasma film (the intermittent activation of which ensures the alternation of opacity/transparency).

Advantageously, the means for moving the radiating object in the longitudinal direction comprise a rail, along which the radiating object can slide, and an electric motor for moving the object on the rail.

Other means for moving the radiating object between the proximal position and the distal position can be implemented without changing the subject matter and the result of the invention.

In addition to the means for longitudinally moving the object, provision also can be made to provide the device with means for pivoting the radiating object on itself in order to modify the angular aperture of the field measurement.

Advantageously and according to the invention, the sealed box that is impervious to electromagnetic radiation is formed by a box with an internal wall covered with microwave absorbers.

These absorbers are configured to prevent any reflection of the electromagnetic field and to attenuate the emission of the field toward the outside of the sealed box.

The invention also relates to a measuring device, in combination characterized by all or some of the features mentioned above or hereafter.

### LIST OF FIGURES

Further aims, features and advantages of the invention will become apparent upon reading the following description, which is provided solely by way of a non-limiting example and which refers to the appended figures, in which:

FIG. 1 is a schematic perspective view of a measuring device according to one embodiment of the invention equipped with an infrared camera, with the view further comprising a cutaway for viewing the elements present in the measuring device;

FIG. 2 is a schematic perspective view of the device of FIG. 1 on which the radiating object has been moved relative to the heat-sensitive film;

FIG. 3 is a schematic perspective view of a measuring device according to another embodiment of the invention equipped with a camera in the visible domain and with a source for emitting fluorescent light, with the view further comprising a cutaway for viewing the elements present in the measuring device;

FIG. 4 is a schematic perspective view of the device of FIG. 3 on which the radiating object has been moved relative to the heat-sensitive film;

FIG. 5 is a schematic perspective view of a measuring device according to another embodiment of the invention equipped with an additional filter arranged between the radiating object and the heat-sensitive film, with the view further comprising a cutaway for viewing the elements present in the measuring device;

FIG. 6 is a schematic perspective view of a measuring device according to one embodiment of the invention showing the cover of the device in the open position, with the view further comprising a cutaway for viewing the elements present in the measuring device.

### DETAILED DESCRIPTION OF AN EMBODIMENT OF THE INVENTION

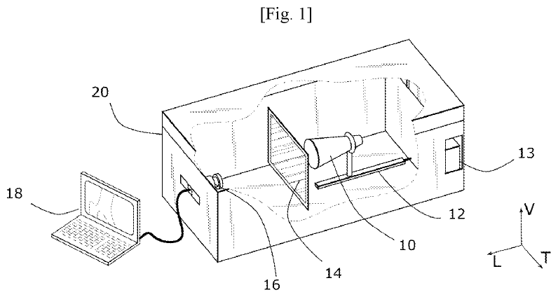

In the figures, the scales and the proportions are not strictly followed for the sake of illustration and clarity. Throughout the whole of the following detailed description with reference to the figures, unless otherwise indicated, each element of the measuring device is described as it is arranged when a radiating object is housed in the sealed box of the measuring device. This configuration is notably shown in FIG. 1.

Furthermore, identical, similar or analogous elements are designated using the same reference signs in all the figures. Finally, the terms longitudinal, transverse and vertical are used in a non-limiting manner with reference to the L, T, V trihedron as shown in FIG. 1. The longitudinal direction corresponds to the main direction of the measuring device along which the radiating object can move. The vertical direction is the direction defined by gravity. The transverse direction is the direction perpendicular to the longitudinal direction and to the vertical direction.

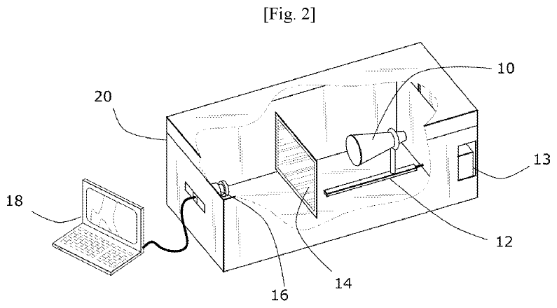

FIGS. 1 and 2 illustrate a device for measuring the electromagnetic radiation of a radiating object 10, such as an antenna, according to a first embodiment.

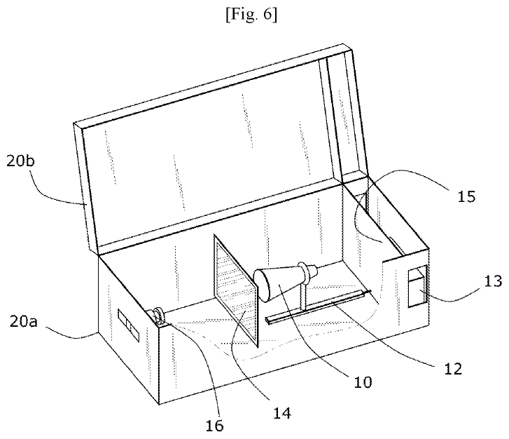

According to this embodiment, the device comprises a sealed box 20 formed by a lower box 20a and a cover 20b, shown in FIG. 6, hinge-mounted on the lower box 20a.

The radiating object 10 is mounted on a sliding rail 12 that forms the means for moving the radiating object 10 in the longitudinal direction L.

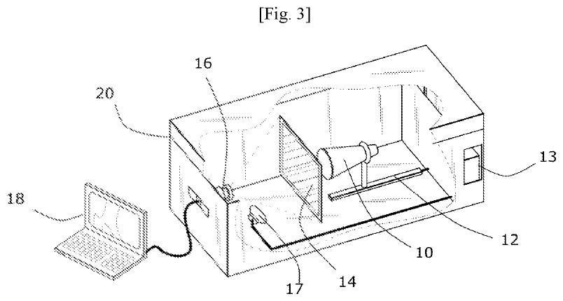

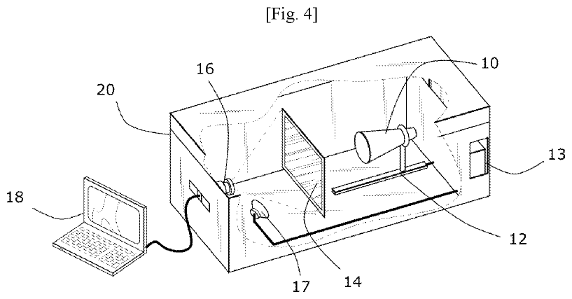

The radiating object 10 can be moved in the longitudinal direction L between a position, called proximal position, schematically shown in FIGS. 1 and 3, and a position, called distal position, schematically shown in FIGS. 2 and 4.

This movement can be obtained by motorized means (not shown in the figures) such as an electric motor driving the radiating object 10 along the rail 12.

The measuring device also comprises means 13 for modulating the radiation of the radiating object. These means are housed, for example, in a specific compartment 15 arranged at a first longitudinal end of the sealed box 20.

The measuring device also comprises a heat-sensitive film 14, heat-sensitive to the electromagnetic field, housed in the sealed box 20 and transversely extending in the vicinity of the proximal position, i.e., it extends in a plane perpendicular to said longitudinal direction.

The measuring device also comprises a camera 16 housed at a second longitudinal end of the sealed box 20, opposite the radiating object 10 to be measured, relative to the heat-sensitive film 14.

Finally, the measuring device comprises a computer 18 forming the means for processing the images acquired by the camera 16. This computer 18 comprises software routines configured to provide a map of the electromagnetic field picked up by the heat-sensitive film 14.

In the embodiment of FIGS. 1 and 2, the camera 16 is an infrared camera configured to be able to directly capture the heating of the heat-sensitive film.

In the embodiment of FIGS. 3 and 4, the camera 16 is a camera in the visible domain and the camera is configured to be able to capture the fluorescent light emitted by the heat-sensitive film 14 covered by a fluorophore. To this end, the device further comprises a light source 17 that illuminates the heat-sensitive film 14. In this case, the camera 16 is provided with an optical filter adapted to the wavelength of the fluorescent light emitted by the heat-sensitive film covered with the fluorophore. The material that covers the heat-sensitive film can be Rhodamine B, for example, the maximum fluorescence intensity of which is approximately 600 nm at ambient temperature when it is subjected to light with a wavelength of 470 nm.

Irrespective of the embodiment, the principle of the invention is based on the interaction of the film 14 with the field radiated by the radiating object 10.

This heat-sensitive film 14 is either weakly conductive (for the electric field measurement), or is insulating and has magnetic losses (for the magnetic field measurement). Thus, under the effect of the field, the film heats (typically within a range of 0.01 to 10° C.). This heating is directly recorded by the infrared camera (for the embodiment of FIGS. 1 and 2), or is even responsible for a variation in the fluorescence intensity (for the embodiment of FIGS. 3 and 4), which is recorded by the camera 16.

The radiation of the radiating object 10 causes the film 14 (which is a thin film, i.e., of very limited thickness compared to the thickness of skin and the wavelength: the field and the temperature are assumed to be constant in the thickness of the film) to heat proportional to the absorbed power density, according to the following formula:

$$Δ T = \frac{{P}_{abs} . e}{2 h}$$

where e represents the thickness of the film 14 and h is a convection coefficient. The absorbed power density is provided by the following equation:

$${P}_{abs} = \frac{1}{2} [ ( σ + 2 π f {ε}^{″} ) {E}^{2} + ( 2 π f {μ}^{″} ) {H}^{2} ]$$

where f represents the frequency of the radiation, σ represents the conductivity of the film 14, ε″ represents its permittivity (imaginary component), and μ″ represents its magnetic permeability (imaginary component).

For the electric field measurement, the measuring device is equipped with a film “with electrical losses”, i.e., with low permittivity and negligible permeability, but with non-zero conductivity. Thus, only the first component of the preceding equation is taken into account and the power is proportional to the square of the electric field.

For the magnetic field measurement, the measuring device is equipped with a film “with magnetic losses”, i.e., with high permeability, but negligible conductivity and permittivity. Thus, only the second component of the preceding equation is taken into account and the power is proportional to the square of the magnetic field.

Thus, for the embodiment of FIGS. 1 and 2 (infrared camera), the computer 18 comprises software routines configured to reconstruct, from the thermal images acquired by the camera 16, the map of the amplitude of the (electrical or magnetic) field in the plane (Oxy) of the film, from the square root of the heating and with a coefficient of proportionality k that only depends on the film. The software means are programmed to compute the following amplitudes:
for a film with electrical losses, |E(x, y)|=k_{E}\sqrt{ΔT(x, y)};
for a film with magnetic losses, |H(x, y)|=k_{H}\sqrt{ΔT(x, y)}.

For the embodiment of FIGS. 3 and 4 (visible and fluorescence camera), the image processing means 18 are configured to reconstruct, from the optical images captured by the camera 16, the map of the amplitude of the (electrical or magnetic) field in the plane (Oxy) of the film, from the square root of the fluorescence intensity (signal received by the camera) and with a coefficient g. In general, the fluorescence decreases with the temperature; the fluorescence in the absence of a field (“cold”) yields an intensity I₀, which is therefore lowered by the field (by means of the temperature variation of the film that it induces) by I_{fluo}. The processing means 18 comprise, for example, software means programmed to compute the amplitudes:
for a film with electrical losses, |E(x, y)|=g_{E}\sqrt{I₀(x, y)−I_{fluo}(x, y)};
for a film with magnetic losses, |H(x, y)|=g_{H}\sqrt{I₀(x, y)−I_{fluo}(x, y)}.

As indicated above, the heat-sensitive film 14 depends on the type of measurement to be carried out. This film is preferably detachably mounted in the sealed box 20 in order to be able to be easily installed/replaced as a function of the type of measurement to be carried out.

For the measurement of the amplitude of the electric field (E) of the radiating object 10, a weakly conductive thin film 14 is used, made up of a composite material based on an electrically insulating matrix and electrically conductive particles. The electrically conductive particulate filler must be adjusted so that the absorbent material has “low” surface impedance (=resistivity/thickness), i.e., surface impedance ranging between 500 and 3,000Ω, so that it absorbs only part of the electric field. This surface impedance is adjusted as a function of the concentration of particles in the insulating matrix and of the thickness of the layer of absorbent material. A carbon-filled polyimide (Kapton) that is a few tens of microns thick is an example of a film that can be used.

For the magnetic field measurement, a composite material based on an electrically insulating matrix and on magnetic particles is used. The density of ferromagnetic particles must remain low enough in order to limit the absorption and therefore the disturbance provided on the field intended to be measured. In practice, polymer matrix films containing iron particles (10 to 20% by volume fraction) are perfectly usable. Neutral films (electrically and magnetically) onto which a solution containing magnetic nanoparticles is deposited also can be contemplated, with a concentration and a thickness adapted to the measurement.

The measuring device also preferably comprises a compartment 15 housing the means 12 for modulating the radiation of the radiating object.

These modulation means depend on the type of radiating object whose radiation is intended to be measured.

In particular, the measuring device according to the invention can have a transient mode and a low-frequency modulation mode.

Within the context of a rapid transient phenomenon (not implementing complex thermal phenomena such as conduction, convection, etc.), directly recording the images allows electromagnetic interpretation and field transcription.

Within the context of a direct harmonic power supply of the source (CW), that is its standard mode if it is an antenna, for example, a low-frequency modulation (from a few tenths of Hz to a few Hz) of the source, associated with filtering of the recorded images (synchronous detection), allows the aforementioned thermal phenomena to be eliminated, namely, conduction in the film and convection with ambient air. Furthermore, this synchronous demodulation allows the signal-to-noise ratio and the measurement dynamics to be improved. Indeed, the thickness of the film is of the order of a hundred microns or less. With the typical features of Kapton (measurement of E) or even of a polymer matrix film (measurement of H), the thermal time constants τ of the films, provided by the following formula, are a few seconds:

$$τ = \frac{ρ Ce}{2 h}$$

where C corresponds to the heat capacity (in J/kg/K), ρ is the density (in kg/m³), h is a convection coefficient in (W/m²/K) and e is the thickness of the film in m.

The convective equilibrium is reached in a few seconds (the film increases in temperature according to an exponential law in (1−e^{-t/τ}) and stabilizes), but the LF modulation does not give it time to do so. Thus, the increase in temperature is reduced, and linearizable (for example, in a triangle for square-all-or-nothing modulation of the source).

Thus, the modulation system is arranged to apply a modulation time sequence of the electromagnetic radiation to which the film is exposed. The synchronous detection system is arranged to filter the intensities captured in successive images of the surface of the film, in accordance with the modulation time sequence. This can be carried out during the measurement or even after recording is complete, by Fast Fourier transform (FFT), for example.

In the case where the radiating source cannot be controlled, a shutter (mechanical or electrical) placed in front of the sensor film and controlled to open/close, allows the modulation (for all-or-nothing) to be recreated, which allows measurement by synchronous detection and corresponds to the previous case. The mechanical shutter can be formed, for example, by two parallel gates, each masking 50% of the film, with one laterally oscillating over a distance equal to the step of the gate, allowing 50% opening (superimposed gates) or closing (gates offset by one step). The electric shutter can be a liquid-crystal or plasma film (the intermittent activation of which ensures the alternation of opacity/transparency).

The device according to the invention allows the radiating object 10 to move along the longitudinal rail 12.

The device according to the invention therefore allows the electromagnetic radiation of the radiating object 10 to be measured in different planes located at different distances from the heat-sensitive film 14. The device according to the invention thus allows a 3D reconstruction of the near-field amplitude to be produced by the image processing means 18.

In particular, in the case of an antenna, amplitude measurements in two distinct planes allow the phase of the field to be obtained at any point of the aperture of the antenna, and thus allow the radiation pattern of this antenna to be reconstructed. To this end, the image processing means can use software means to implement the method known as “Planar Near-Field Far-Field Phase Retrieval”.

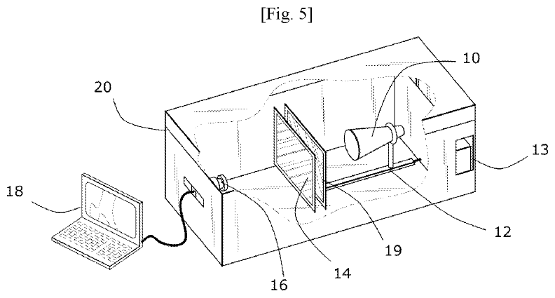

FIG. 5 illustrates an alternative embodiment of the measuring device in which a filter 19 is arranged between the radiating object 10 to be measured and the heat-sensitive film 14. This filter is configured to filter a component of the electromagnetic field so as to allow measurement of the other components of the electromagnetic radiation of the object to be measured. This filter 19 is, for example, formed by a thin film of the conductive grid or absorbent grid type or of the type with particular patterns, notably polarization selective surfaces (PSS). It allows only the unfiltered components to pass over the heat-sensitive film 14.

1. A device for measuring the electromagnetic radiation of a radiating object (10), comprising:
a sealed box (20), impervious to electromagnetic radiation, extending in a longitudinal direction (L) and equipped with an opening adapted to allow said radiating object (10) to be measured to be housed in said box;
means (13) for modulating the radiation of said radiating object;
characterized in that it further comprises:
means (12) for moving said radiating object (10) inside the sealed box (20) in the longitudinal direction (L) between a position, called proximal position, and a position, called distal position;
a heat-sensitive film (14), heat-sensitive to the electromagnetic field, housed in said sealed box (20) and extending in a plane perpendicular to said longitudinal direction in the vicinity of said proximal position;
a camera (16) housed at a longitudinal end of said sealed box (20), opposite said radiating object (10) to be measured relative to the heat-sensitive film (14), and configured to acquire images of said heat-sensitive film, with said heat-sensitive film (14) being arranged at the focal distance from said camera (16);
means (18) for processing said images acquired by said camera (16) configured to provide a map of the electromagnetic field of said radiating object (10) picked up by said heat-sensitive film (4).

2. The device as claimed in claim 1, characterized in that said camera (16) is equipped with an image acquisition sensor in the visible domain and in that it further comprises a monochromatic light source (17) oriented so as to illuminate the heat-sensitive film (14) and in that said film is coated with a layer of a fluorescent material.

3. The device as claimed in claim 1, characterized in that said camera (16) is a camera equipped with an infrared sensor.

4. The device as claimed in any of claims 1 to 3, characterized in that said means (13) for modulating the radiation of said radiating object (10) comprise a microcontroller, a synthesizer and a radio frequency or microwave amplifier housed in a dedicated compartment (15).

5. The device as claimed in any of claims 1 to 3, characterized in that said means (13) for modulating the radiation of said radiating object comprise:
a shutter screen arranged between said radiating object (10) and said heat-sensitive film (14), with said shutter screen being configured to be able to transition from a state, called transparent state, in which the radiation of said radiating object can reach said heat-sensitive film, to a state, called opaque state, in which said screen prevents said radiation from said radiating object from reaching said heat-sensitive film;
control electronics configured to control said shutter screen between the opaque state and the transparent state, and vice versa.

6. The device as claimed in any of claims 1 to 5, characterized in that it further comprises a filter (19) arranged between said radiating object (10) to be measured and said heat-sensitive film (14), with said filter (19) being configured to filter a component of the electromagnetic field so as to allow measurement of the other components of the electromagnetic radiation of said radiating object (10) to be measured.

7. The device as claimed in any of claims 1 to 6, characterized in that said heat-sensitive film (14) is an anisotropic film comprising an array of patterns for determining the spatial variation of the amplitude and the direction of the field (for linear polarization), or even the spatial variation of the amplitude and the degree of ellipticity (for circular polarization) of the field radiated by said radiating object (10).

8. The device as claimed in any of claims 1 to 7, characterized in that said heat-sensitive film (14) is detachably mounted inside said sealed box (20).

9. The device as claimed in any of claims 1 to 8, characterized in that said means (12) for moving said radiating object (10) in the longitudinal direction (L) comprise a rail, along which said radiating object (10) can slide, and an electric motor for moving said object on said rail.

10. The device as claimed in any of claims 1 to 9, characterized in that said sealed box (20) impervious to electromagnetic radiation is formed by a box with an internal wall covered with microwave absorbers.
